(19) United States
(12) Patent Application Publication
(10) Pub. No.: US 2026/0018538 A1
(43) Pub. Date: Jan. 15, 2026

(54) ELECTRONIC DEVICE

(71) Applicant: Advanced Semiconductor Engineering, Inc., Kaohsiung (TW)

(72) Inventors: Chih-Pin HUNG, Kaohsiung (TW); Cheng-Yuan KUNG, Kaohsiung (TW); Yung-Shun CHANG, Kaohsiung (TW)

(73) Assignee: Advanced Semiconductor Engineering, Inc., Kaohsiung (TW)

(21) Appl. No.: 19/246,673

(22) Filed: Jun. 23, 2025

Related U.S. Application Data
(60) Provisional application No. 63/670,709, filed on Jul. 12, 2024.

(51) Int. Cl. H01L 23/00; H01L 23/34

(52) U.S. Cl. CPC H01L 23/562; H01L 23/34

(57) ABSTRACT

An electronic device and method of manufacturing the same are provided. The electronic device includes a temperature-sensitive structure, a first multilayer structure, and a second multilayer structure. The temperature-sensitive structure has a first surface and a second surface opposite to the first surface. The first multilayer structure is disposed under the first surface of the temperature-sensitive structure and configured to cause a first residual stress in response to a first temperature change. The second multilayer structure is disposed over the second surface and configured to cause a second residual stress in response to a second temperature change. The second residual stress substantially eliminates the first residual stress so that the temperature-sensitive structure, the first multilayer structure and the second multilayer structure constitute a less-temperature-sensitive structure.

### CROSS-REFERENCE TO RELATED APPLICATION

This application claims the benefit of and priority to U.S. Provisional Patent Application 63/670,709, filed Jul. 12, 2024, which is incorporated herein by reference in its entirety.

### BACKGROUND

### 1. Field of the Disclosure

The present disclosure relates to an electronic device, and particularly to an electronic device including a temperature sensitive structure.

### 2. Description of the Related Art

Due to the ongoing reduction in the size of electronic devices, new challenges have arisen in relation to process window and equipment limitations. One such challenge is the warpage of the intermediate structure, which can result in low manufacturing yield. Consequently, there is a need for a new electronic device and a method for its manufacturing.

### SUMMARY

In some embodiments, an electronic device includes a temperature-sensitive structure, a first multilayer structure, and a second multilayer structure. The temperature-sensitive structure has a first surface and a second surface opposite to the first surface. The first multilayer structure is disposed under the first surface of the temperature-sensitive structure and configured to cause a first residual stress in response to a first temperature change. The second multilayer structure is disposed over the second surface and configured to cause a second residual stress in response to a second temperature change. The second residual stress substantially eliminates the first residual stress so that the temperature-sensitive structure, the first multilayer structure and the second multilayer structure constitute a less-temperature-sensitive structure.

In some embodiments, an electronic device includes a substrate, a first redistribution structure, a second redistribution structure, and a third redistribution structure. The substrate has a first surface and a second surface opposite to the first surface. The first redistribution structure is disposed under the first surface and has a first line width/line space (L/S). The second redistribution structure is disposed over the second surface and has a second L/S substantially equal to the first L/S. The third redistribution structure is disposed over the second surface and has a third L/S different from the first L/S.

In some embodiments, a method of manufacturing an electronic device includes: providing a temperature-sensitive structure having a first surface and a second surface opposite to the first surface; forming a first multilayer structure under the first surface of the temperature-sensitive structure and configured to cause a first residual stress in response to a first temperature change; and forming a second multilayer structure over the second surface subsequent to forming the first multilayer structure and configured to cause a second residual stress in response to a second temperature change.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an example of an electronic device according to some embodiments of the present disclosure.

FIG. 2A illustrates one or more stages of an example of a method for manufacturing a confining structure according to some embodiments of the present disclosure.

FIG. 2B illustrates one or more stages of an example of a method for manufacturing a confining structure according to some embodiments of the present disclosure.

FIG. 2C and FIG. 2C-1 illustrate one or more stages of an example of a method for manufacturing a confining structure according to some embodiments of the present disclosure.

FIG. 2D illustrates one or more stages of an example of a method for manufacturing a confining structure according to some embodiments of the present disclosure.

FIG. 2E and FIG. 2E-1 illustrate one or more stages of an example of a method for manufacturing a confining structure according to some embodiments of the present disclosure.

FIG. 2F and FIG. 2F-1 illustrate one or more stages of an example of a method for manufacturing a confining structure according to some embodiments of the present disclosure.

FIG. 2G illustrates one or more stages of an example of a method for manufacturing a confining structure according to some embodiments of the present disclosure.

FIGS. 3A, 3B, and 3C illustrate the relation between one of the intermediate structures of an electronic device and warpage according to some embodiments of the present disclosure.

FIGS. 4A, 4B, and 4C illustrate the relation between one of the intermediate structures of an electronic device and warpage according to some embodiments of the present disclosure.

FIGS. 5A, 5B, and 5C illustrate the relation between one of the intermediate structures of an electronic device and warpage according to some embodiments of the present disclosure.

FIGS. 6A, 6B, and 6C illustrate the relation between one of the intermediate structures of an electronic device and warpage according to some embodiments of the present disclosure.

FIGS. 7A, 7B, and 7C illustrate the relation between one of the intermediate structures of an electronic device and warpage according to some embodiments of the present disclosure.

FIGS. 8A, 8B, and 8C illustrate the relation between one of the intermediate structures of an electronic device and warpage according to some embodiments of the present disclosure.

FIGS. 9A, 9B, and 9C illustrate the relation between one of the intermediate structures of an electronic device and warpage according to some embodiments of the present disclosure.

FIGS. 10A, 10B, and 10C illustrate the relation between one of the intermediate structures of an electronic device and warpage according to some embodiments of the present disclosure.

FIG. 11 illustrates a cross-sectional view of an example of an electronic device according to some embodiments of the present disclosure.

FIG. 12 illustrates a cross-sectional view of an example of an electronic device according to some embodiments of the present disclosure.

FIG. 13 illustrates a cross-sectional view of an example of an electronic device according to some embodiments of the present disclosure.

FIG. 14 illustrates an enlarged view of the optical module of an electronic device according to some embodiments of the present disclosure.

FIG. 15 illustrates a cross-sectional view of an example of an optical module according to some embodiments of the present disclosure.

FIGS. 16A, 16B, 16C, 16D, and 16E illustrate one or more stages of an example of a method for manufacturing an optical module according to some embodiments of the present disclosure.

FIG. 17 illustrates a top view of a wafer according to some embodiments of the present disclosure.

FIG. 18 illustrates a top view of a panel according to some embodiments of the present disclosure.

FIGS. 19A, 19B, 20A, and 20B illustrate the change in warpage at various stages of a comparative example.

FIGS. 21A, 21B, 22A, and 22B illustrate the change in warpage at various stages of a comparative example.

Common reference numerals are used throughout the drawings and the detailed description to indicate the same or similar components. Embodiments of the present disclosure will be readily understood from the following detailed description taken in conjunction with the accompanying drawings.

### DETAILED DESCRIPTION

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

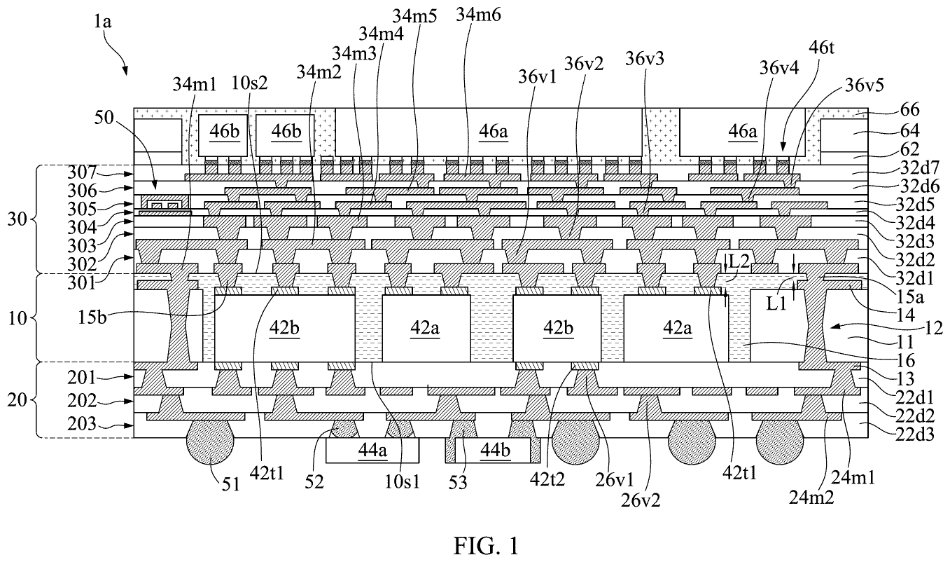

FIG. 1 illustrates a cross-sectional view of an example of an electronic device 1a according to some embodiments of the present disclosure. In some arrangements, the electronic device 1a may include a substrate 10, a multilayer structure 20, a multilayer structure 30, and electronic components 42a, 42b, 44a, 44b, 46a, and 46b.

In some arrangements, the substrate 10 (or carrier) may be a temperature sensitive structure. For example, the warpage of the substrate 10 may vary relatively significantly in response to changes in temperature within or around the substrate 10. In some arrangements, the substrate 10 is more sensitive to the temperature changes than the electronic device 1a. In some arrangements, the substrate 10 is more temperature sensitive than the structure including or composed of the substrate 10, the multilayer structure 20, and the multilayer structure 30. The substrate 10 may have a surface 10s1 (or a lower surface) and a surface 10s2 (or an upper surface) opposite to the surface 10s1. In some arrangements, the thickness of the substrate 10 may range between about 80 μm and about 800 μm. The substrate 10 may include a core 11, a via 12, a conductive trace 13, and a conductive trace 14, via 15a, via 15b, and a protection layer 16. In this disclosure, the warpage of a structure may be measured or determined by a distance (or length) between the uppermost point and the lowermost point of said structure. For example, the warpage of the substrate 10 may be defined as a distance between the topmost of the surface 10s1 and the bottommost of the surface 10s2.

In some arrangements, the core 11 may include a core substrate. The core substrate may include polyimide, polypropylene, prepreg, or other suitable materials. In some embodiments, a resin material used in the core substrate may be a fiber-reinforced resin so as to strengthen the core substrate, and the reinforcing fibers may be, without limitation, glass fibers or Kevlar fibers (aramid fibers). In some arrangements, the core 11 may be configured to define openings for accommodating active components, passive components, or other suitable components that have relatively large dimensions or that are configured to regulate power and/or signal and be electrically connected between two devices.

The via 12 may extend between the upper surface and the lower surface of the core 11. In some arrangements, the via 12 may include a seed layer on the core 11 and a conductive material on the seed layer. The seed layer may include, for example, copper, titanium, stainless steel, another metal or metal alloy, or a combination thereof. The conductive material may include, for example, copper, chromium, tin, gold, silver, nickel, aluminum, or other suitable materials.

The conductive trace 13 may be disposed on or below the lower surface of the core 11. The conductive trace 13 may be electrically coupled to the via 12. The material of the conductive trace 13 may be the same as or similar to that of the via 12.

The conductive trace 14 may be disposed on or over the upper surface of the core 11. The conductive trace 14 may be electrically coupled to the via 12. The material of the conductive trace 14 may be the same as or similar to that of the via 12.

The electronic components 42a and 42b may abut the surface 10s1 of the substrate 10. Each of the electronic components 42a and 42b may include an active or passive component. The active component may include, for example, an application processor (AP), system-on-a-chip (SoC), central processing unit (CPU), graphics processing unit (GPU), microcontroller, etc., a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies) or other active components. The passive component may include a capacitor, an inductor, a resistor, or other suitable components. The capacitor may include a deep trench capacitor (DTC), a multi-layer ceramic capacitor (MLCC), or other capacitors, which may be configured to filter high frequency signals and/or low frequency signals. In some arrangements, the electronic component 42a and/or 42b may include a bridge die, which is configured to electrically connect two electronic components (e.g., electronic components 46a). In some arrangements, the electronic component 42a may include terminals 42t1 on or over the upper surface of the electronic component 42a. In some arrangements, the electronic component 42b may include terminals 42t1 on or over the upper surface of the electronic component 42b and terminals 42t2 on or under the lower surface of the electronic component 42b. In some arrangements, the electronic components 42a and 42b may have different thicknesses.

In some arrangements, the via 15a may be disposed on or over the upper surface of the core 11. The via 15a may be electrically coupled to the conductive trace 14. The via 15a may penetrate a portion of the protection layer 16. In some arrangements, each of the vias 15b may be disposed on or over the upper surface of the electronic component 42a or electronic component 42b. The via 15b may be electrically coupled to the electronic component 42a and/or electronic component 42b. The via 15b may penetrate a portion of the protection layer 16. The via 15a may have a length (or vertical length) L1. The via 15b may have a length (or vertical length) L2. In some arrangements, the length L1 may be different from the length L2. In some arrangements, the length L1 may be less than the length L2. In some arrangements, the depths or lengths of the vias 15b may be different due to different thicknesses of the electronic components 42 and 42b

In some arrangements, the protection layer 16 may encapsulate the substrate 10, the electronic component 42a, the electronic component 42b, the via 15a, and the via 15b. The protection layer 16 may include resin or other suitable materials. The protection layer 16 may have a relatively large CTE (e.g., the CTE between 20 and 30). In some arrangements, the lower surface of the protection layer 16 may be defined as the surface 10sl, and the upper surface of the protection layer 16 may be defined as the surface 10s2. In some arrangements, the protection layer 16 may function as a planarization layer which provides a substantially flat surface (e.g. surface 10s2). In some cases, the electronic components 42a and 42b have different thicknesses, the protection layer 16 may reduce the ratio of the distance between the electronic component 42a and the surface 10s2 to the distance between the electronic component 42b and the surface 10s2. Accordingly, the multilayer structure 30 may be formed over the substrate 10 with better yield and quality. In some arrangements, the lower surface of the core 11 may be substantially aligned with the surface 10s1 of the substrate 10. In some arrangements, the lower surface of the electronic component 42a (or 42b) may be substantially aligned with the surface 10s1 of the substrate 10. In some cases, the core 11 has openings for accommodating the electronic components 42a and 42b as well as the protection layer 16, generating interfaces between different materials. As a result, the substrate 10 may be relatively temperature sensitive. The CTE mismatch may cause the substrate 10 to have a relatively large warpage when temperature changes.

In some arrangements, the substrate 10 may include a conductive trace 34m1. The conductive trace 34m1 may be disposed on or over the substrate 10 and/or embedded within the dielectric layer 32d1. In some arrangements, the conductive trace 34m1 may be electrically connected to the substrate 10 by the via 15a. In some arrangements, the conductive trace 34m1 may be electrically connected to the electronic component 42a (or 42b) by the via 15b. The conductive trace 34m1 may be configured to reduce the aspect ratio of a via that electrically connects to the electronic component 42a (or 42b). If the conductive traces 34m1 are not formed, the via's aspect ratio may be excessively large, leading to an increased presence of voids.

The multilayer structure 20 may be disposed on or under the surface 10s1 of the substrate 10. In some arrangements, the multilayer structure 20 may include dielectric layers 22d1, 22d2, and 22d3. The dielectric layer 22d1 may be disposed on or under the substrate 10. The dielectric layer 22d2 may be disposed on or under the dielectric layer 22d1. The dielectric layer 22d3 may be disposed on or under the dielectric layer 22d2. In some arrangements, the dielectric layer 22d3 may define openings for accommodating electrical connectors and/or electronic components. Each of the dielectric layers 22d1, 22d2, and 22d3 may include polyimide, polypropylene, prepreg, epoxy-based material, inorganic materials (e.g., silicon, glass, ceramic or quartz), liquid and/or dry-film materials or a combination thereof. In some arrangements, the dielectric layers 22d1, 22d2, and 22d3 may be free of Ajinomoto Build-up Flm (ABF).

In some arrangements, the multilayer structure 20 may include conductive traces 24m1 and 24m2 as well as conductive vias 26v1 and 26v2. The conductive trace 24m1 may be disposed on or under the dielectric layer 22d1 and/or embedded within the dielectric layer 22d2. The conductive trace 24m2 may be disposed on or under the dielectric layer 22d2 and/or embedded within the dielectric layer 22d3. The conductive via 26v1 may extend between the conductive trace 13 and the conductive trace 24m1. The conductive via 26v1 may be embedded within the dielectric layer 22d1. The conductive via 26v2 may extend between the conductive traces 24m1 and 24m2. The conductive via 26v2 may be embedded within the dielectric layer 22d2.

In some arrangements, the multilayer structure 20 may include layers 201, 202, and 203. The layer 201 may include conductive trace 13, dielectric layer 22d1, and conductive via 26v1. The layer 202 may include conductive trace 24m1, dielectric layer 22d2, and conductive via 26v2. The layer 203 may include conductive trace 24m2 and dielectric layer 22d3.

The electronic components 44a and 44b may be disposed on or under the dielectric layer 22d3. Each of the electronic components 44a and 44b may be an active or passive component. The active component may include, for example, application processor (AP), system-on-a-chip (SoC), central processing unit (CPU), graphics processing unit (GPU), microcontroller, etc., a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies) or other active components. The passive component may include a capacitor, an inductor, a resistor, or other suitable components. The capacitor may include a deep trench capacitor (DTC), a multi-layer ceramic capacitor (MLCC) or other capacitors, which may be configured to filter high frequency signals and/or low frequency signals.

The electronic device 1a may include electrical connectors 51, 52, and 53. The electrical connectors 51, 52, and 53 may be at least partially disposed within the openings of the dielectric layer 22d3. The electrical connector 51 may be configured to connect an external device to the electronic device 1a. The electrical connector 52 may be electrically coupled to the electronic component 44a. The electrical connector 53 may be electrically coupled to the electronic component 44b. The electrical connector 53 may cover the lateral surface of the electronic component 44b. Each of the electrical connectors 51, 52, and/or 53 may include a solder ball, such as a controlled collapse chip connection (C4) bump, a ball grid array (BGA), a land grid array (LGA), or so on. In some embodiments, the electrical connectors 51, 52, and 53 may include a solder material(s), which may include alloys of gold and tin solder or alloys of silver and tin solder, or other suitable materials.

The multilayer structure 30 may be disposed on or over the surface 10s2 of the substrate 10. The multilayer structure 30 may be configured to reduce or substantially eliminate the warpage of the substrate 10 and the multilayer structure 20. In some arrangements, the multilayer structure 30 may include dielectric layers 32d1, 32d2, 32d3, 32d4, 32d5, 32d6, and 32d7. The dielectric layer 32d1 may be disposed on or over the substrate 10. The dielectric layer 32d2 may be disposed on or over the dielectric layer 32d1. The dielectric layer 32d3 may be disposed on or over the dielectric layer 32d2. The dielectric layer 32d4 may be disposed on or over the dielectric layer 32d3. The dielectric layer 32d5 may be disposed on or over the dielectric layer 32d4. The dielectric layer 32d6 may be disposed on or over the dielectric layer 32d5. The dielectric layer 32d7 may be disposed on or over the dielectric layer 32d6. In some arrangements, the dielectric layer 32d7 may define openings for accommodating electrical connectors and/or electronic components. Each of the dielectric layers 32d1 to 32d7 may include polyimide, polypropylene, prepreg, epoxy-based material), inorganic materials (e.g., silicon, glass, ceramic or quartz), liquid and/or dry-film materials or a combination thereof. In some arrangements, the dielectric layers 32d1 to 32d7 may be free of ABF. In some arrangements, the thickness of the dielectric layer 32d4 (or 32d5, 32d6, or 32d7) may be less than that of the dielectric layer 32d3 (or 32d1 or 32d2). In some arrangements, the thickness difference between the dielectric layers 32d1 (or 32d2 or 32d3) and 22d1 (or 22d2) may be less than the thickness difference between the dielectric layers 32d1 (or 32d2 or 32d3) and 32d4 (or 32d5, 32d6, or 32d7).

In some arrangements, the multilayer structure 30 may include conductive traces 34m1, 34m2, 34m3, 34m4, 34m5, and 34m6 as well as conductive vias 36v1, 36v2, 36v3, 36v4, and 36v5. The conductive trace 34m1 may be disposed on or over the substrate 10 and/or embedded within the dielectric layer 32d1. In some arrangements, the conductive trace 34m1 may be electrically connected to the substrate 10 by the via 15a. In some arrangements, the conductive trace 34m1 may be electrically connected to the electronic component 42a (or 42b) by the via 15b. The conductive trace 34m1 may be configured to reduce the aspect ratio of a via that electrically connects to the electronic component 42a (or 42b). If the conductive traces 34m1 are not formed, the via's aspect ratio may be excessively large, leading to an increased presence of voids.

The conductive trace 34m2 may be disposed on or over the dielectric layer 32d1 and/or embedded within the dielectric layer 32d2. The conductive trace 34m3 may be disposed on or over the dielectric layer 32d2 and/or embedded within the dielectric layer 32d3. The conductive trace 34m4 may be disposed on or over the dielectric layer 32d4 and/or embedded within the dielectric layer 32d5. The conductive trace 34m5 may be disposed on or over the dielectric layer 32d5 and/or embedded within the dielectric layer 32d6. The conductive trace 34m6 may be disposed on or over the dielectric layer 32d6 and/or embedded within the dielectric layer 32d7. In some arrangements, the thickness of the conductive traces 34m4, 34m5, and 34m6 may be less than that of the conductive traces 34m1, 34m2, and 34m3.

The conductive via 36v1 may extend between the conductive trace 34m1 and the conductive trace 34m2. The conductive via 36v1 may be embedded within the dielectric layer 32d1. The conductive via 36v2 may extend between the conductive trace 34m2 and the conductive trace 34m3. The conductive via 36v2 may be embedded within the dielectric layer 32d2. The conductive via 36v3 may extend between the conductive trace 34m3 and the conductive trace 34m4. The conductive via 36v3 may be embedded within the dielectric layer 32d4. The conductive via 36v4 may extend between the conductive trace 34m4 and the conductive trace 34m5. The conductive via 36v4 may be embedded within the dielectric layer 32d5. The conductive via 36v5 may extend between the conductive trace 34m5 and the conductive trace 34m6. The conductive via 36v5 may be embedded within the dielectric layer 32d6.

In some arrangements, the conductive traces 24m1, 24m2, 34m1, 34m2, and 34m3 as well as the conductive vias 26v1, 26v2, 36v1, and 36v2 have a first line width/line space (L/S). In some arrangements, the conductive traces 34m4, 34m5, and 34m6, as well as conductive vias 36v4, and 36v5 have a second L/S. In some arrangements, the vias 15a and via 15b as well as conductive traces 13 and 14 have a third L/S. In some arrangements, the second L/S is less than the first L/S. In some arrangements, the first L/S is substantially equal to the third L/S. In some arrangements, the first L/S ranges between about 5/5 μm and about 40/40 μm. In some arrangements, the second L/S ranges between about 0.8/0.8 μm and about 5/5 μm. In some arrangements, the third L/S ranges between about 5/5 μm and about 40/40 μm. In some arrangements, the thickness of the conductive traces 34m1, 34m2, and 34m3 may be substantially equal to the thickness of the conductive traces 24m1 and 24m2.

In some arrangements, the electronic components 46a and 46b may be disposed on or over the multilayer structure 30. Each of the electronic components 46a and 46b may include, for example, an application processor (AP), system-on-a-chip (SoC), central processing unit (CPU), graphics processing unit (GPU), microcontroller, etc.; a memory die (e.g., dynamic random access memory (DRAM) die, static random access memory (SRAM) die, high bandwidth memory (HBM), etc.); a power management die (e.g., power management integrated circuit (PMIC) die); a radio frequency (RF) die; a sensor die; a micro-electro-mechanical-system (MEMS) die; a signal processing die (e.g., digital signal processing (DSP) die); a front-end die (e.g., analog front-end (AFE) dies); or other active components. The passive component may include a capacitor, an inductor, a resistor, or other suitable components. The capacitor may include a deep trench capacitor (DTC), a multi-layer ceramic capacitor (MLCC) or other capacitors, which may be configured to filter high frequency signals and/or low frequency signals. In some arrangements, the electronic components 46a and 46b may have different thicknesses.

In some arrangements, the multilayer structure 30 may include layers 301, 302, 303, 304, 305, 306, and 307. The layer 301 may include the dielectric layer 32d1 and conductive via 36v1. The layer 302 may include conductive trace 34m2, dielectric layer 32d2, and conductive via 36v2. The layer 303 may include conductive trace 34m3 and dielectric layer 32d3. The layer 304 may include dielectric layer 32d4 and conductive via 36v3. The layer 305 may include conductive trace 34m4, dielectric layer 32d5, and conductive via 36v4. The layer 306 may include conductive trace 34m5, dielectric layer 32d6, and conductive via 36v5. The layer 307 may include conductive trace 34m6 and dielectric layer 32d7. The components of the layers 301, 302, and 303 may have dimensions greater than those of the layers 304, 305, 306, and 307.

In some arrangements, the electronic device 1a may include a passive component 50. The passive component 50 may include an inductor. The passive component 50 may be embedded within the dielectric layer 32d4 and dielectric layer 32d5. In some arrangements, the passive component 50 may have a shell covering conductive layers. The shell may have a lower layer over the dielectric layer 32d3 and an upper layer within the dielectric layer 32d4 as well as pillars extending between the upper layer and the lower layer. The shell may include a magnetic material or other suitable materials. In some arrangements, the conductive layer may be disposed on or over the dielectric layer 32d4. In some arrangements, the conductive layer of the passive component 50 and the conductive trace 34m4 may be formed by the same stage.

In some arrangements, the electronic device 1a may include terminals 46t. The terminal 46t may be at least partially disposed within the openings of the dielectric layer 32d7. The terminal 46t may electrically couple the electronic component 46a (or electronic component 46b) and the multilayer structure 30. In some arrangements, the terminal 46t may include multiple layers. For example, the terminal 46t may include a combination of copper layer, nickel layer, gold layer, solder layer, or other suitable conductive layers.

In some arrangements, the electronic device 1a may include an adhesive layer 62 and a stiffener 64. The adhesive layer 62 may be disposed on or over the dielectric layer 32d7. The adhesive layer 62 may be configured to attach the stiffener 64 to the multilayer structure 30. The stiffener 64 may be disposed at a peripheral region of the electronic device 1a. For example, the stiffener 64 may surround the electronic components 46a and 46b. The stiffener 64 may have a ring-shaped profile in a top view. The stiffener 64 may be configured to reinforce the structure. The stiffener 64 may include metal, alloy, or other suitable materials.

In some arrangements, the electronic device 1a may include an encapsulant 66. In some arrangements, the encapsulant 66 may be disposed on or over the dielectric layer 32d7. In some arrangements, the encapsulant 66 may encapsulate the electronic component 46a, the electronic component 46b, the adhesive layer 62, and the stiffener 64. In some arrangements, the upper surface of the electronic component 46a may be substantially aligned with the upper surface of the encapsulant 66. In some arrangements, the encapsulant 66 may cover the upper surface of the electronic component 46b. In some arrangements, the encapsulant 66 may cover the upper surface of the stiffener 64. The encapsulant 66 may include insulation or dielectric material. In some embodiments, the encapsulant 66 may be made of molding material that may include, for example, a novolac-based resin, an epoxy-based resin, a silicone-based resin, or other suitable encapsulant. Suitable fillers may also be included, such as powdered SiO₂.

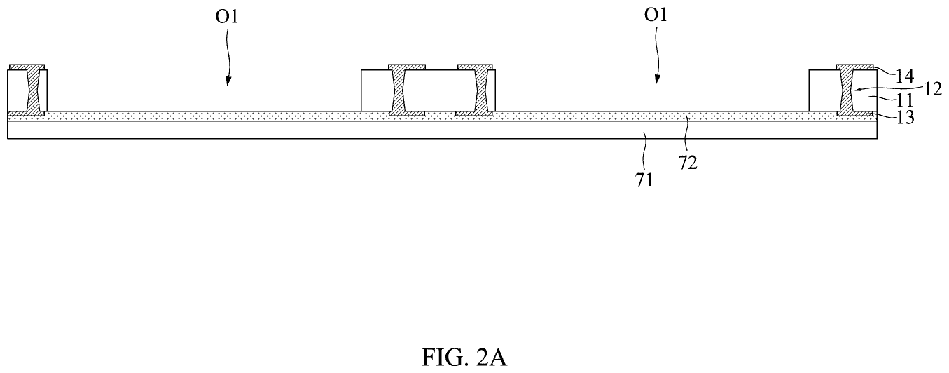

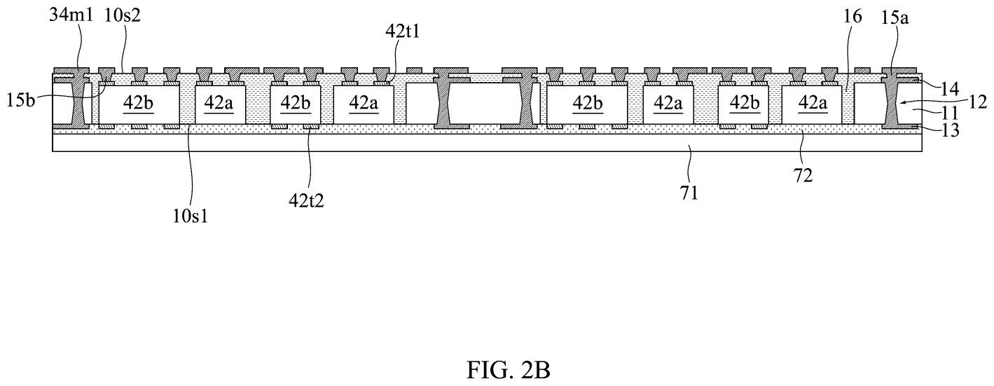

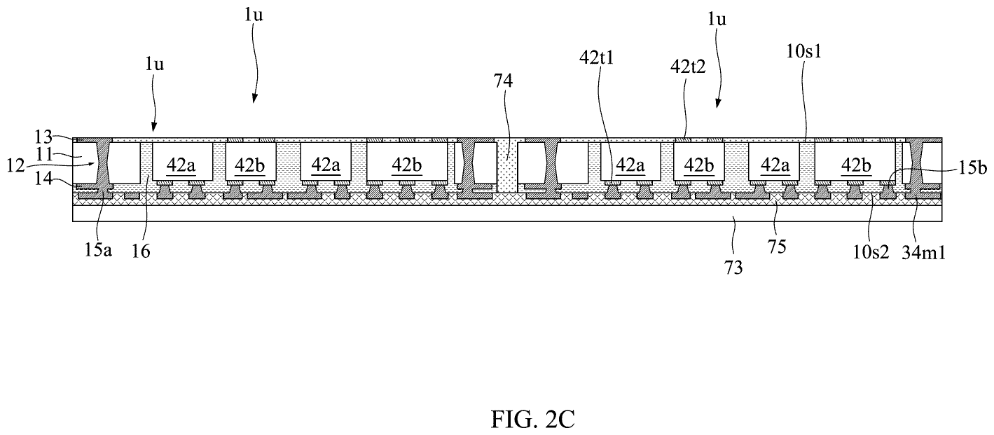

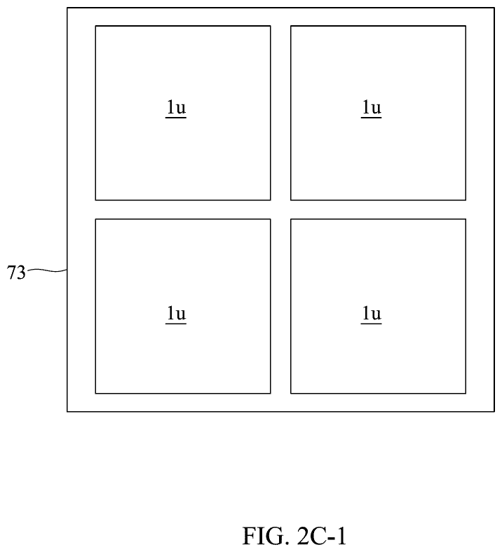

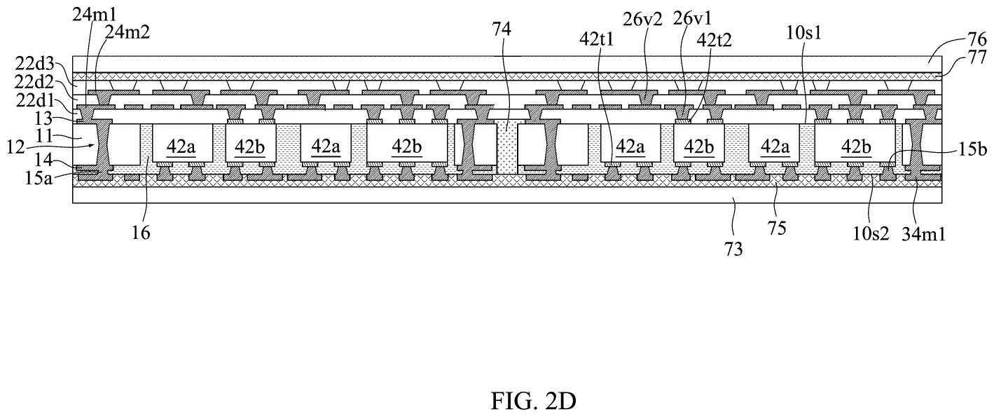

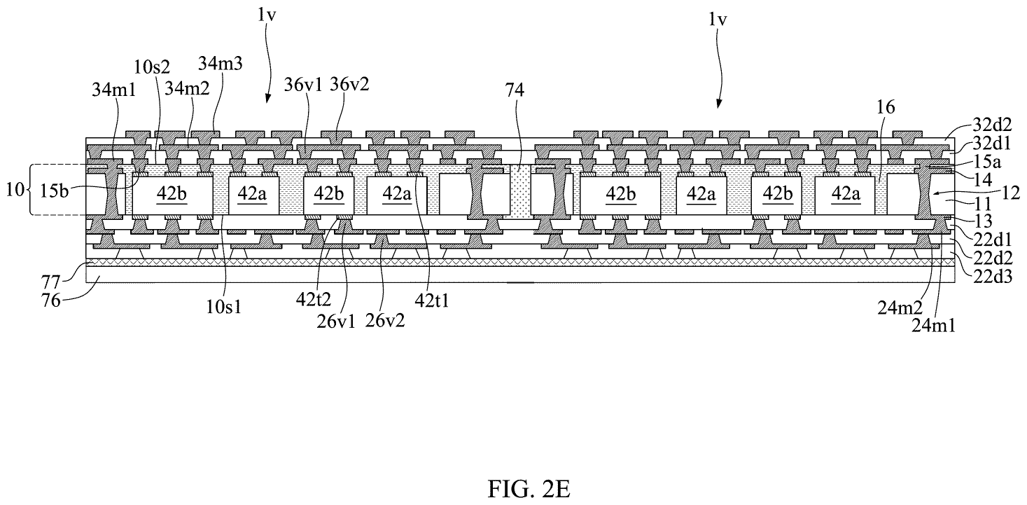

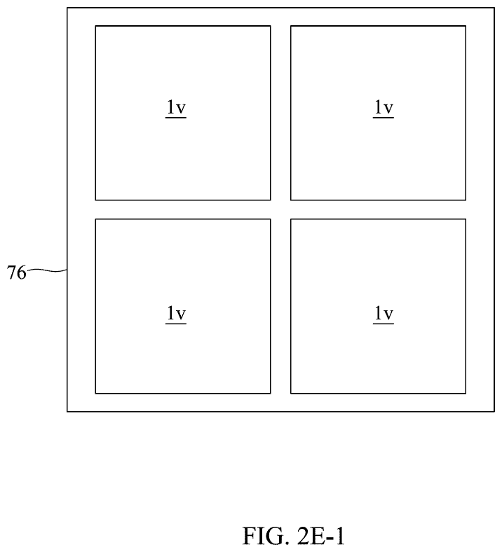

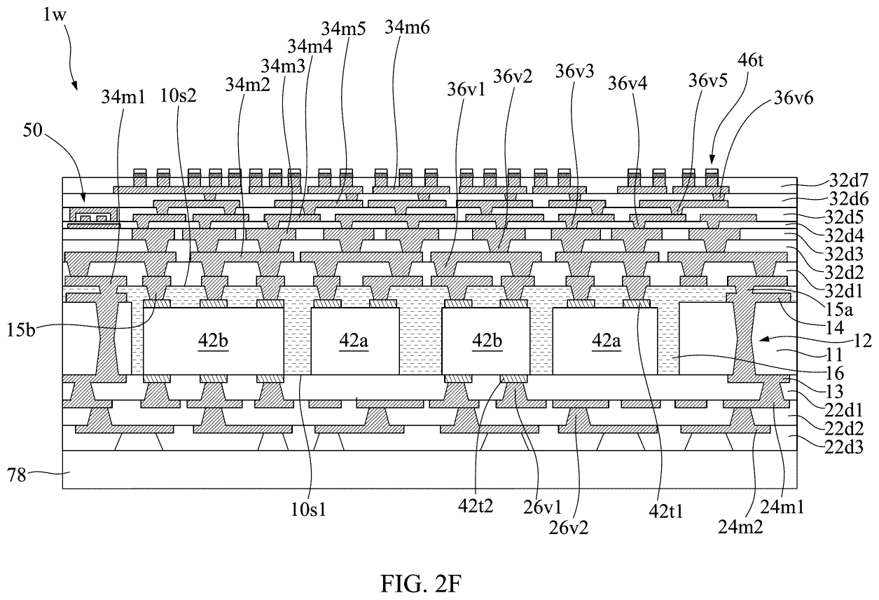

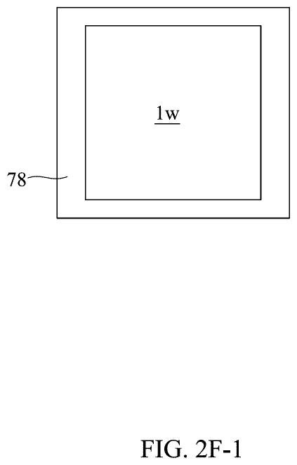

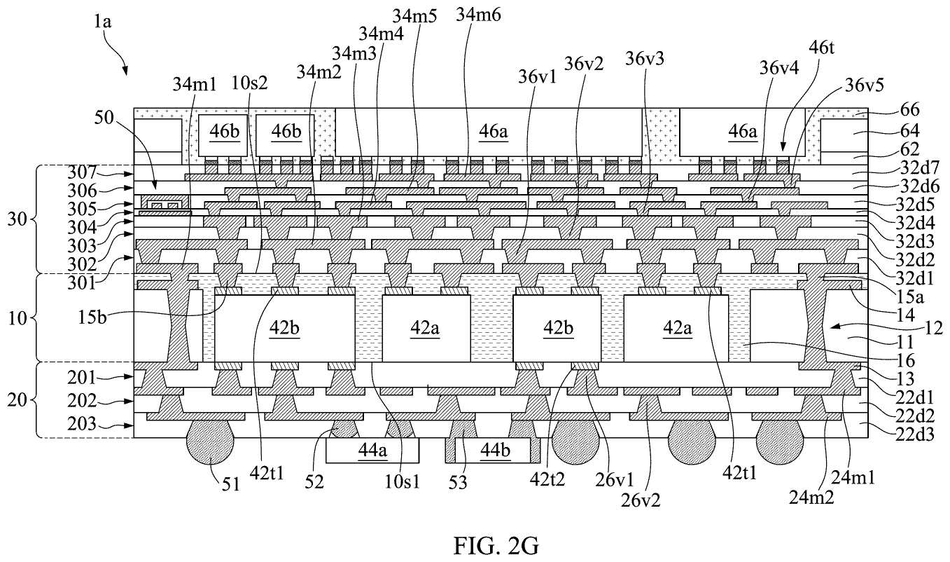

FIGS. 2A to 2G illustrate stages of an example of a method for manufacturing a confining structure according to some embodiments of the present disclosure.

Referring to FIG. 2A, a carrier 71 may be provided. The carrier 71 may be a glass carrier, a plastic carrier, a ceramic carrier, a polymer carrier, or other suitable carriers. A release film 72 may be disposed on or over the carrier 71. The core 11, via 12, conductive trace 13, and conductive trace 14 may be formed on or over the release film 72. In some arrangements, the core 11 may define a plurality of openings O1 for accommodating electronic components or other components.

Referring to FIG. 2B, the electronic components 42a and 42b may be formed on or over the carrier 71 and within the openings of the core 11. The protection layer 16 may be formed to cover the core 11. The conductive trace 34m1, the via 15a, and the via 15b may be formed.

Referring to FIGS. 2C and 2C-1, the carrier 71 and the release film 72 may be removed. The core 11 may be sawed to form multiple units 1u. Each of the units 1u may have a dimension of about 300 mm×300 mm. A carrier 73 may be provided. The conductive trace 34m1 may be attached to the carrier 73 through a release film 75. The carrier 73 may be a glass carrier, a plastic carrier, a ceramic carrier, a polymer carrier, or other suitable carriers. In some arrangements, the carrier 73 may have a relatively large dimension. For example, the carrier 73 may have a dimension of about 600 mm×600 mm or greater. In this arrangements, the dimension (e.g., surface area) of the carrier 73 may be substantially equal to or greater than the sum of the dimensions of four units 1u. An encapsulant 74 may be formed to encapsulate the units 1u. The encapsulant 74 may be ground to expose the terminals 42t2.

Referring to FIG. 2D, the dielectric layer 22d1, dielectric layer 22d2, dielectric layer 22d3, conductive trace 24m1, conductive trace 24m2, conductive via 26v1, and conductive via 26v2 may be formed on the surface 10s1 of the substrate 10 with a relatively large L/S (e.g., from about 5/5 μm to about 40/40 μm). In some arrangements, a portion of the encapsulant 74 may be removed to expose the electronic components 42a and 42b. In other arrangements, the encapsulant 74 may remain on the electronic components 42a and 42b. Openings may be formed on the dielectric layer 22d3. The dielectric layer 22d3 may be attached to a carrier 76 through a release film 77. The carrier 76 may be a glass carrier, a plastic carrier, a ceramic carrier, a polymer carrier, or other suitable carriers. In some arrangements, the carrier 76 may have a relatively large dimension. For example, the carrier 76 may have a dimension of about 600 mm×600 mm or greater. In this arrangements, the dimension (e.g., surface area) of the carrier 76 may be substantially equal to or greater than the sum of the dimensions of four units 1v. In some arrangements, the dielectric layers 22d1 and 22d2 may be formed by coating or other suitable techniques.

Referring to FIGS. 2E and 2E-1, the carrier 73 and the release film 75 may be removed. The dielectric layer 32d1, dielectric layer 32d2, dielectric layer 32d3, conductive trace 34m2, conductive trace 34m3, conductive via 36v1, and conductive via 36v2 may be formed on or over the surface 10s2 of the substrate 10 with a relatively large L/S (e.g., from about 5/5 μm to about 40/40 μm). The units 1v may be defined and disposed on the carrier 76. Each of the units 1v may have a dimension of about 300 mm×300 mm. In some arrangements, the dielectric layers 32d1 to 32d3 may be formed by coating or other suitable techniques. In this stage, the warpage of the unit 1v may be measured.

Referring to FIGS. 2F and 2F-1, the units 1v may be sawed and separated. A carrier 78 may be provided. The carrier 78 may be a glass carrier, a plastic carrier, a ceramic carrier, a polymer carrier, or other suitable carriers. In some arrangements, the carrier 78 may have a relatively small dimension. For example, the carrier 78 may have a dimension of 300 mm×300 mm. Due to the relatively small dimensions or pitches of the conductive traces and vias to be formed subsequently, the equipment used for defining the pattern of the dielectric layer and/or conductive layer differs from that used for producing conductive traces and vias with larger dimensions or pitches. As a result, the dimensions of the carriers vary for different equipment and processes.

The dielectric layer 32d4, dielectric layer 32d5, dielectric layer 32d6, dielectric layer 32d7, conductive trace 34m4, conductive trace 34m5, conductive trace 34m6, conductive via 36v3, conductive via 36v4, and conductive via 36v5 may be formed with a relatively small L/S (e.g., from about 0.8/0.8 μm to about 5/5 μm). The unit(s) 1w may be defined over the carrier 78. Each of the units 1w may have a dimension of about 300 mm×300 mm. In this arrangements, the dimension (e.g., surface area) of the carrier 78 may be substantially equal to or greater than the dimension of one unit 1w. The terminal 46t may be formed on or over the conductive trace 34m6. In some arrangements, the dielectric layer 32d4 to dielectric layer 32d7 may be formed by coating or other suitable techniques. In some arrangements, the layers and or thicknesses of the dielectric layer produced in this stage may be modified in response to the warpage of the structure as shown in FIG. 2E.

Referring to FIG. 2G, the electronic components 46a and 46b may be formed over the terminal 46t. The adhesive layer 62 and stiffener 64 may be formed on or over the dielectric layer 32d7. The encapsulant 66 may be formed over the dielectric layer 32d7. The carrier 78 may be removed. The electrical connectors 51, 52, and 53 may be formed on or under the conductive trace 24m2. The electronic components 44a and 44b may be formed. The encapsulant 66 may be formed to cover the electronic components 44a and 44b. As a result, the electronic device 1a may be produced.

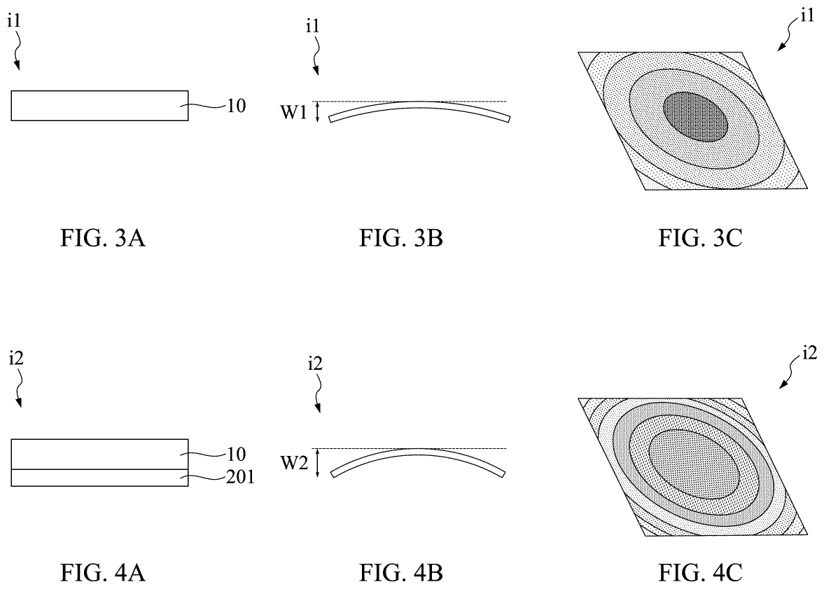

FIGS. 3A-10A, 3B-10B, and 3C-10C illustrate the relation between intermediate structures of an electronic device and warpage according to some embodiments of the present disclosure. FIGS. 3A-10A illustrate cross-sectional views of the intermediate structures of an electronic device, FIGS. 3B-10B illustrate the warpages of the intermediate structures of FIGS. 3A-10A, respectively, and FIGS. 3C-10C illustrate the warpage maps of the intermediate structures of FIGS. 3A-10A, respectively. The density of the dots shown in FIGS. 3C-10C may represent the height, with regions containing a higher concentration of dots indicating elevated areas.

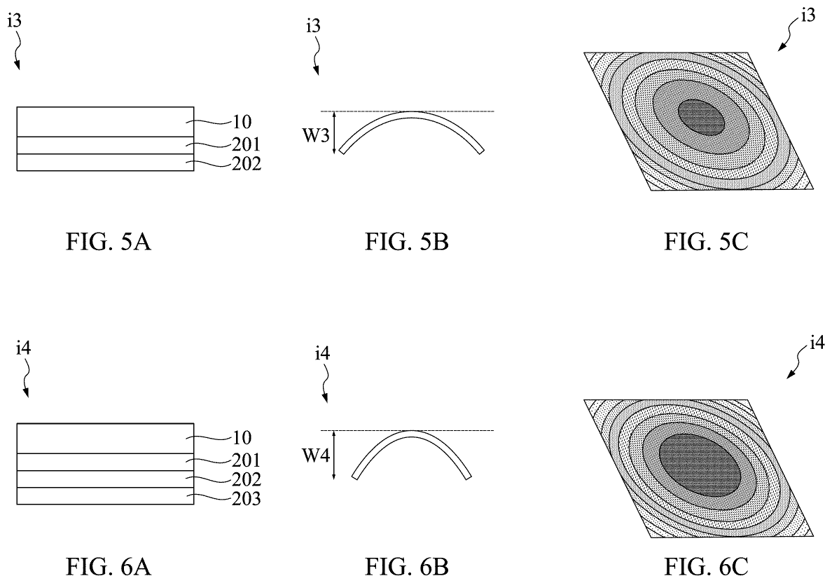

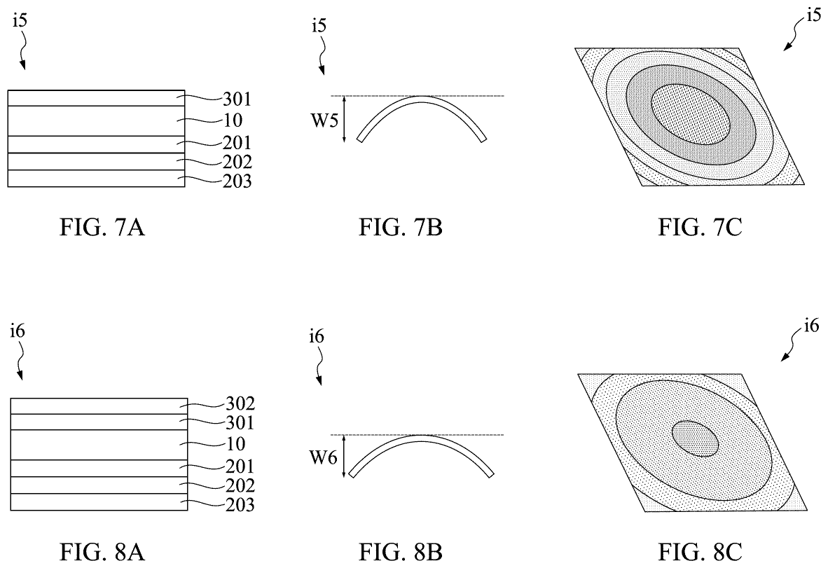

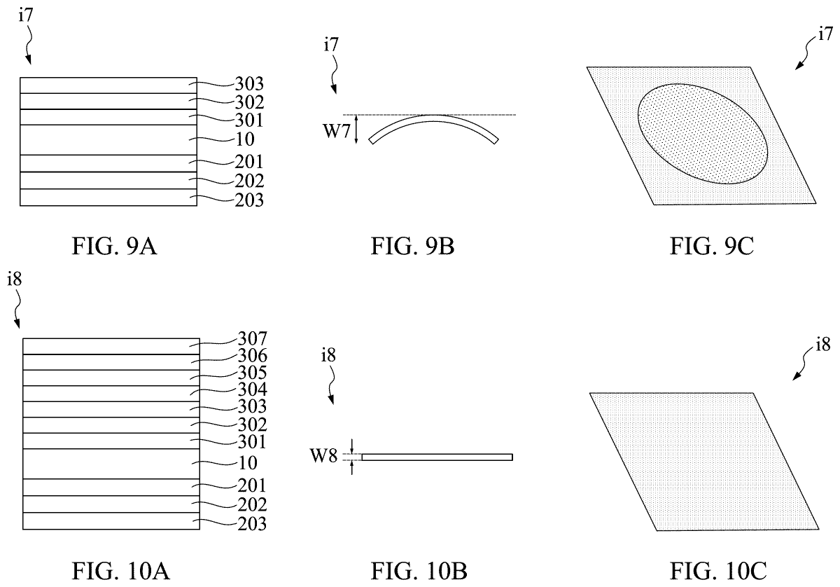

As shown in FIGS. 3A, 3B, and 3C, the structure i1 may include the substrate 10. The structure i1 may have a warpage W1. As shown in FIGS. 4A, 4B, and 4C, the structure i2 may include or be composed of the substrate 10 and the layer 201. The structure i2 may have a warpage W2 greater than the warpage W1. As shown in FIGS. 5A, 5B, and 5C, the structure i3 may include or be composed of the substrate 10 and the layer 201 and the layer 202. The structure i3 may have a warpage W3 greater than the warpage W2. As shown in FIGS. 6A, 6B, and 6C, the structure i4 may include or be composed of the substrate 10 and the layers 201 to 203. The structure i4 may have a warpage W4 greater than the warpage W3. As shown in FIGS. 7A, 7B, and 7C, the structure i5 may include or be composed of the substrate 10, the layers 201 to 203, and the layer 301. The structure i5 may have a warpage W5 less than the warpage W4. As shown in FIGS. 8A, 8B, and 8C, the structure i6 may include or be composed of the substrate 10, the layers 201 to 203, the layer 301, and the layer 302. The structure i6 may have a warpage W6 less than the warpage W5. As shown in FIGS. 9A, 9B, and 9C, the structure i7 may include or be composed of the substrate 10, the layers 201 to 203, and the layers 301 to 303. The structure i7 may have a warpage W7 less than the warpage W6. As shown in FIGS. 10A, 10B, and 10C, the structure i8 may include or be composed of the substrate 10, the layers 201 to 203, and the layers 301 to 307. The structure i8 may have a warpage W8 less than the warpage W7. In some arrangements, the warpage W8 is less than the warpage W2. The structure i8 is a less-temperature-sensitive structure in comparison with the structure i2. The structure i8 is a less-temperature-sensitive structure in comparison with the structure i5. In this disclosure, the term “less-temperature-sensitive” may refer to a structure that exhibits reduced warpage (or smaller changes in warpage) in response to temperature variations.

In this arrangement, the multilayer structure 30 can be designed to effectively control, reduce, and/or substantially eliminate the warpage of the overall structure. Additionally, the number of layers in the multilayer structure 30 can be adjusted. In a comparative example, the formation of the upper redistribution structure does not account for the warpage induced by the lower redistribution structure. As a result, the overall structure experiences a relatively significant warpage. In the arrangement, the warpage induced by the multilayer structure 20 is controlled, reduced, and/or substantially eliminated by the multilayer structure 30 that includes at least two dimensions (e.g., L/S). The layers of the multilayer structure 30 with larger L/S, formed first, can control and/or reduce a significant portion of the warpage. Subsequently, the layers with smaller L/S, formed later, can fine-tune the remaining warpage, thereby substantially eliminating the overall warpage of the structure.

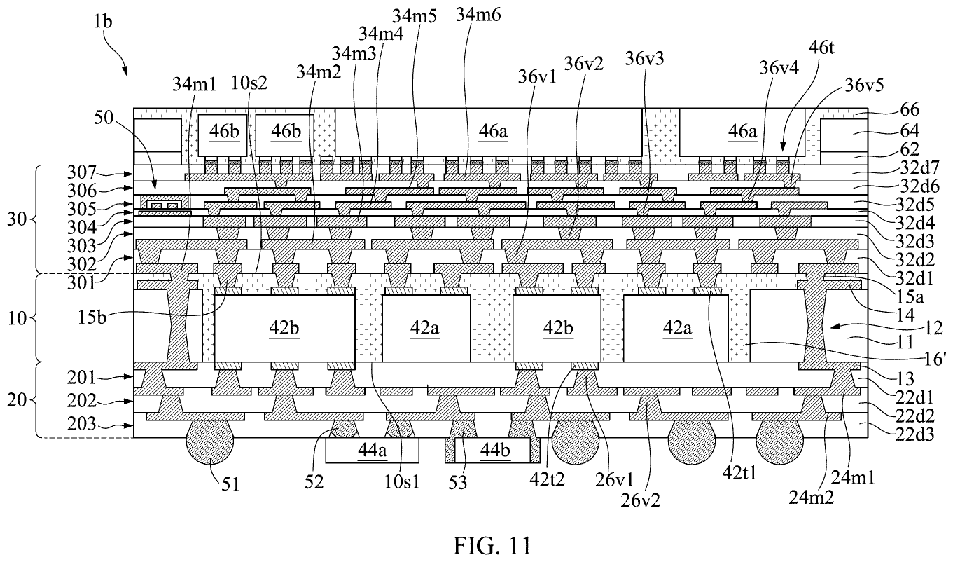

FIG. 11 illustrates a cross-sectional view of an example of an electronic device 1b according to some embodiments of the present disclosure. The electronic device 1b is similar to the electronic device 1a except for the difference(s) described as follows.

In some arrangements, the electronic device 1b may include an encapsulant 16′. In some arrangements, the encapsulant 16′ may include a molding compound. The encapsulant 16′ may include, for example, a novolac-based resin, an epoxy-based resin, a silicone-based resin, or other suitable encapsulant. Suitable fillers may also be included, such as powdered SiO₂. The encapsulant 16′ may have a relatively small CTE (e.g., the CTE between 10 and 20). Therefore, the rigidity of the electronic device 1b may be enhanced.

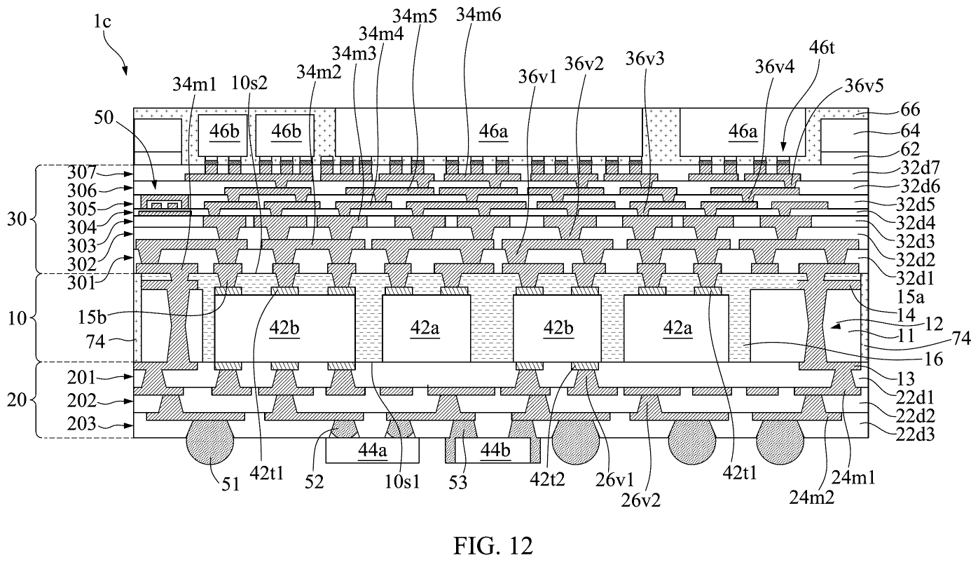

FIG. 12 illustrates a cross-sectional view of an example of an electronic device 1c according to some embodiments of the present disclosure. The electronic device 1c is similar to the electronic device 1a except for the difference(s) described as follows.

In some arrangements, an encapsulant 74 may remain after singulation. In some arrangements, the encapsulant 74 may be disposed on the sidewall of the core 11. In some arrangements, the encapsulant 74 may include a molding compound. The encapsulant 74 may extend between the dielectric layer 22d1 and the dielectric layer 32d1. In some arrangements, the width of the multilayer structures 20 may be greater than that of the substrate 10 (or core 11). In some arrangements, the encapsulant 74 may encapsulate the substrate 10. The lateral surface of the encapsulant 74 may be substantially aligned with the lateral surface of the multilayer structures 20 (or multilayer structures 30). The lateral surface of the core 11 may be misaligned with the lateral surface of the multilayer structures 20 (or multilayer structures 30).

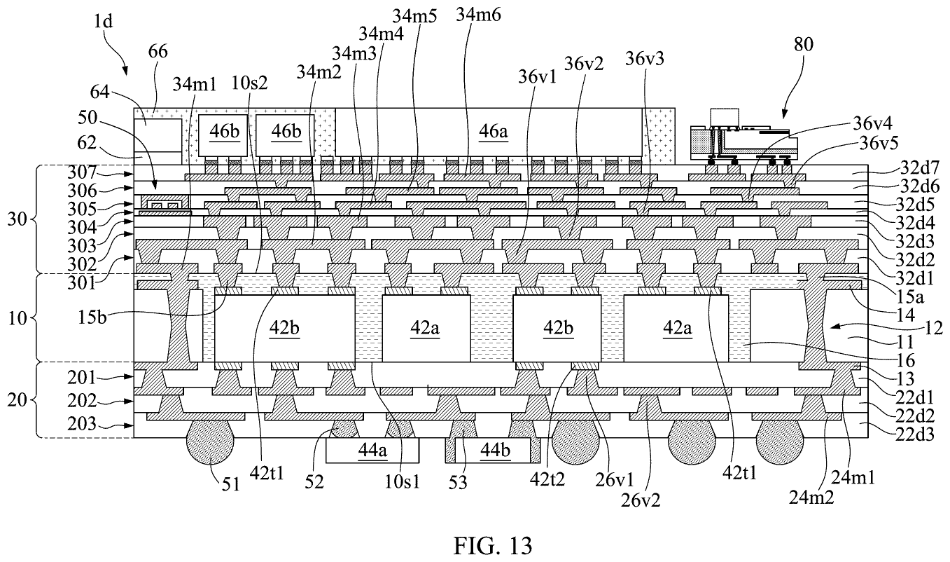

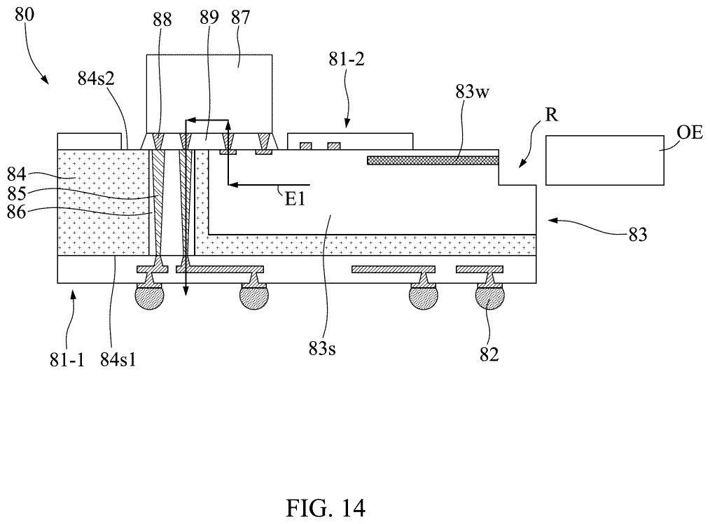

FIGS. 13 and 14 illustrate an example of an electronic device Id according to some embodiments of the present disclosure. The electronic device 1d is similar to the electronic device 1a except for the difference(s) described as follows.

In some arrangements, the electronic device 1d may include an optical module 80 (or optical package). In some arrangements, the optical module 80 may be disposed on or over the dielectric layer 32d7. The optical module 80 may be electrically connected to the electronic component 46a and/or 46b through the multilayer structure 30. The optical module 80 may be electrically connected to the electronic component 42a and/or 42b through the multilayer structure 30. The optical module 80 may be electrically connected to the electronic component 44a and/or 44b through the substrate 10, multilayer structures 20 and 30. Although FIG. 13 illustrates that the optical module 80 is disposed beyond the encapsulant 66, the optical module 80 may be encapsulated by the encapsulant 66 or other encapsulants distinct from the encapsulant 66 in other arrangements. In this arrangement, the optical receiver (e.g., optical element 83w or other elements) of the optical module 80 may be exposed by the encapsulant 66.

As shown in FIG. 14, the optical module 80 may include redistribution structures 81-1 and 81-2, electrical connectors 82, a photonic component 83, an encapsulant 84, an interconnection structure 85, and an electronic component 87. In some arrangements, the photonic component 83 may include a photonic integrated circuit (PIC). The photonic component 83 may be configured to process, receive, and/or transmit optical signals. For example, the photonic component 83 may include a substrate 83s and an optical element 83w. The substrate 83s may include a semiconductor substrate, such as a silicon substrate or other suitable substrate(s). Some active elements and passive elements are formed on or in the semiconductor substrate. In some arrangements, the substrate 83s may define a recess R (or trench) recessed from the upper surface and lateral surface of the substrate 83s. The optical element 83w may be configured to receive an optical signal from an external device OE (e.g., an optical fiber). The optical element 83w may be embedded in the substrate 83s. The optical element 83w may be exposed by the lateral surface of the substrate 83s. The optical element 83w may include an optical waveguide, an acoustic waveguide, an electromagnetic waveguide, or the like. In some arrangements, the upper surface and a portion of the lateral surface of the photonic component 83 may be exposed by the encapsulant 84. In some arrangements, the optical module 80 may include an edge coupler (not labeled) optically coupled to the optical element 83w.

The encapsulant 84 may encapsulate the photonic component 83. The encapsulant 84 may include a molding compound (e.g., an epoxy molding compound or other molding compound). The encapsulant 84 may include a polyimide. The encapsulant 84 may include a phenolic compound or material. The encapsulant 84 may include fillers or particles (e.g. silica particles). The encapsulant 84 may include a surface 84s1 and a surface 84s2 opposite to the surface 84s1.

The redistribution structures 81-1 and 81-2 may be disposed on the surface 84s1 and surface 84s2 of the encapsulant 84, respectively. Each of the redistribution structures 81-1 and 81-2 may be a single-layer or multilayer structure.

The interconnection structure 85 may penetrate the encapsulant 84. The interconnection structure 85 may be electrically connected between the electronic component 87 and redistribution structure 81-1. The interconnection structure 85 may include a conductive pillar, such as a copper pillar or other suitable elements. The interconnection structure 85 may be spaced apart from the encapsulant 84 by a passivation layer 86. The passivation layer 86 may be embedded within the encapsulant 84. The passivation layer 86 may include a dielectric material, such as polyimide or other suitable materials. The material of the passivation layer 86 may be different from that of the encapsulant 84. In some arrangements, the encapsulant 84 and interconnection structure 85 may be replaced by an interposer, such as a silicon interposer that includes through vias penetrating a semiconductor substrate.

The electronic component 87 may be disposed on or over the encapsulant 84. The electronic component 87 may be electrically connected to the photonic component 83. The electronic component 87 may be electrically connected to the interconnection structure 85 through conductive structures 88. The electronic component 87 may include an electric integrated circuit (EIC). In some arrangements, the electronic component 87 may include, for example but is not limited to, a controller die, a processor die, an application specific integrated circuit (ASIC) die, a microcontroller unit (MCU) die, or the like. The electronic component 87 may be configured to process electrical signals received from the photonic component 83. The optical module 80 may include a protection layer 89. The protection layer 89 may be disposed between the encapsulant 84 and the electronic component 87. The protection layer 89 may encapsulate the conductive structures 88. The protection layer 89 may include a capillary underfill (CUF), a molded underfill (MUF), or other suitable materials.

As shown in FIG. 14, the photonic component 83 may be configured to transmit a signal E1 that passes through the electronic component 87, interconnection structure 85, and redistribution structure 81-1.

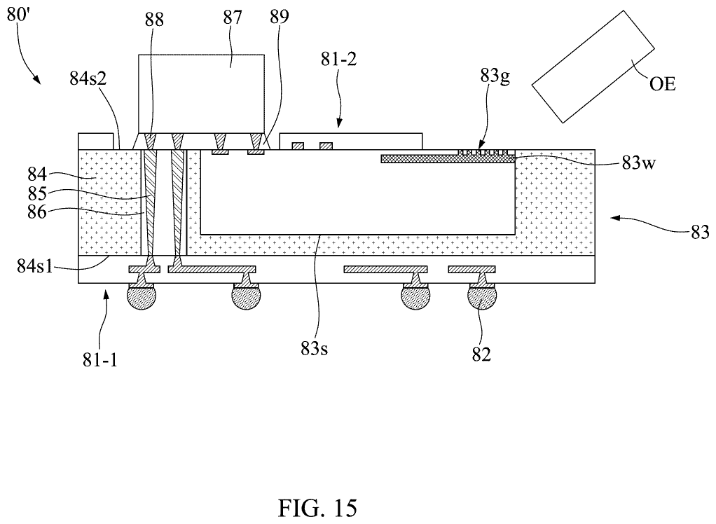

FIG. 15 illustrates a cross-sectional view of an example of an optical module 80′ according to some embodiments of the present disclosure. In some arrangements, the optical module 80 as shown in FIG. 13 may be replaced by the optical module 80′.

In some arrangements, the optical module 80′ may include a grating structure 83g. The grating structure 83g may be exposed from the upper surface of the substrate 83s. The grating structure 83g may include a grating coupler or other suitable elements. The grating structure 83g may receive light beams from the external device OE, and the received light beams are transmitted via the optical element 83w.

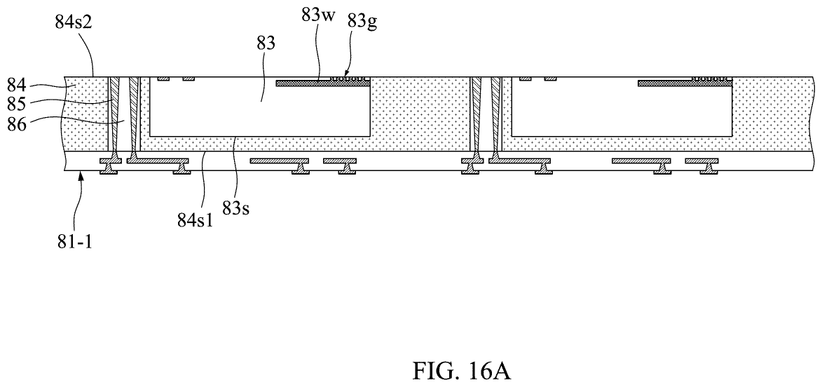

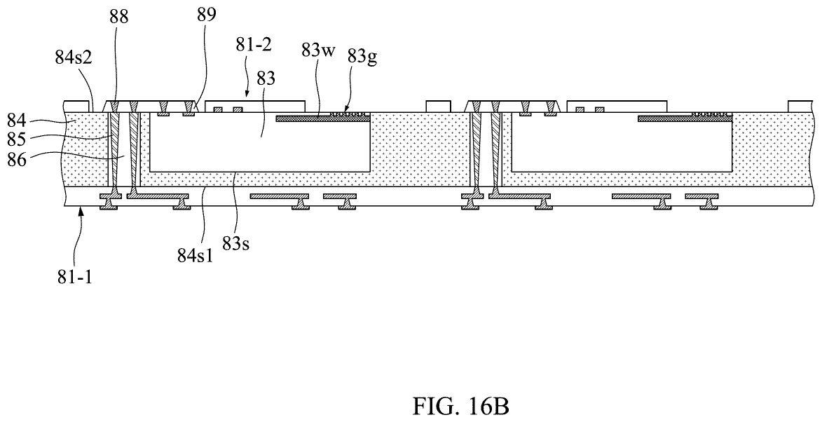

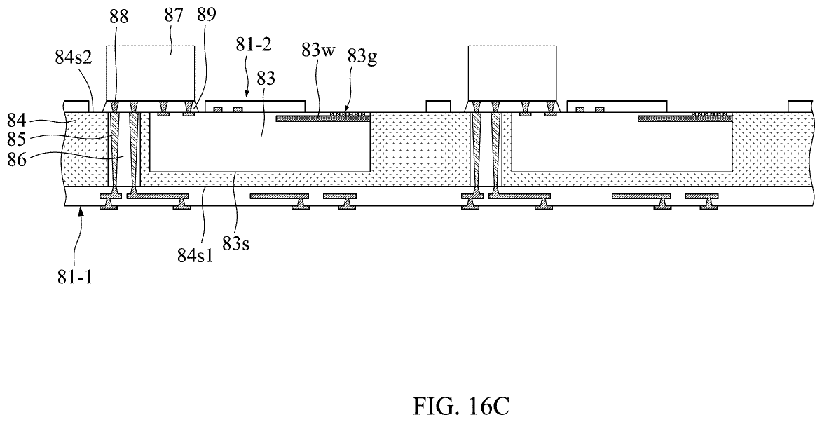

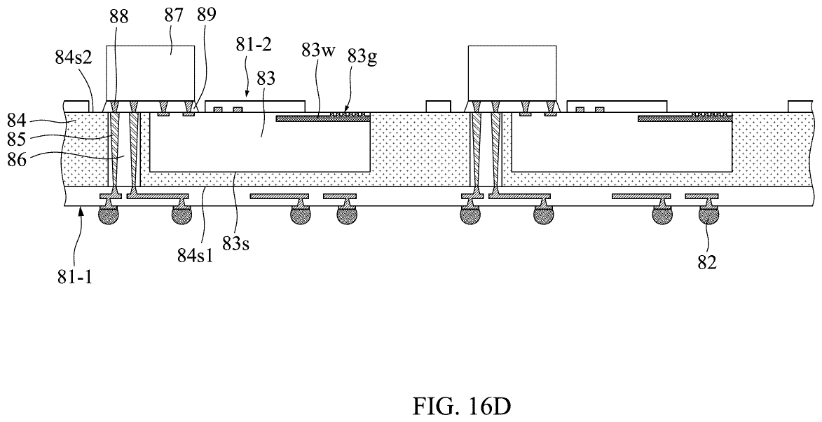

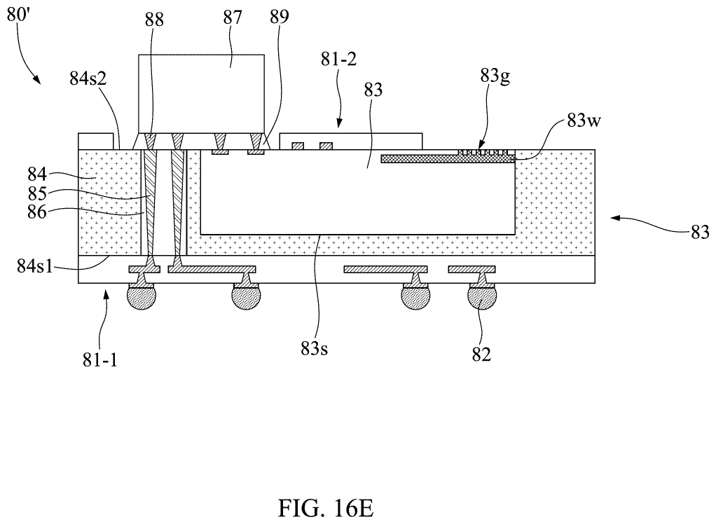

FIGS. 16A, 16B, 16C, 16D, and 16E illustrate one or more stages of an example of a method for manufacturing an optical module according to some embodiments of the present disclosure.

Referring to FIG. 16A, the photonic component 83, interconnection structure 85, and passivation layer 86 may be provided and disposed on a carrier (not shown). The encapsulant 84 may be formed to encapsulate the photonic component 83, interconnection structure 85, and passivation layer 86. The redistribution structure 81-1 may be formed under the surface 84s1 of the encapsulant 84. In this arrangement, the carrier may be a panel carrier. A plurality of optical units may be defined over the carrier. In some arrangements, the plurality of optical units may be arranged in a wafer form or disposed on a wafer. In some arrangements, the plurality of optical units may be arranged in a panel form or disposed on a panel.

Referring to FIG. 16B, the redistribution structure 81-2 may be formed over the surface 84s2 of the encapsulant 84. The conductive structures 88 and protection layer 89 may be formed over the surface 84s2 of the encapsulant 84.

Referring to FIG. 16C, the electronic component 87 may be mounted on the conductive structures 88 and protection layer 89. In this arrangement, the structure as shown in FIG. 16C may be a chip-on-wafer (CoW) or a chip-on-panel (CoP).

Referring to FIG. 16D, the electrical connectors 82 may be formed under the redistribution structure 81-1.

Referring to FIG. 16E, the plurality of optical units may be singulated. A plurality of optical module 80 may be produced.

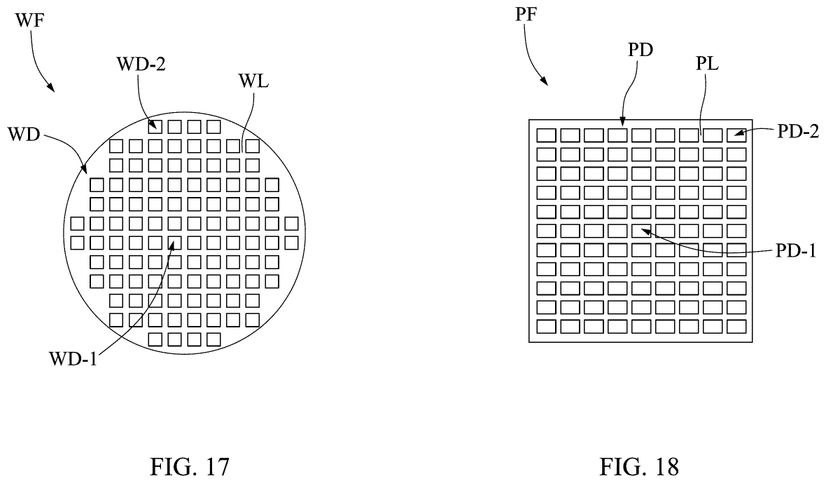

FIGS. 17 and 18 illustrate top views of a wafer WF and panel PF according to some embodiments of the present disclosure.

As shown in FIG. 17, the wafer WF may include a semiconductor wafer, a glass wafer, or other suitable wafers. The wafer WF may have a circular profile or the like. The wafer WF may include a plurality of units WD. Each of the units WD may include a die, a package, a module, a component, or the like. The units WD may be separated from each other by scribe lines WL. The units WD may be separated from each other by a singulation technique. The wafer WF may include a unit WD-1 at a central region and a unit WD-2 at a peripheral region. As shown in FIG. 18, the panel PF may include a semiconductor panel, a glass panel, or other suitable panels. The panel PF may have a rectangular profile or the like. The panel PF may include a plurality of units PD. Each of the units PD may include a die, a package, a module, a component, or the like. The units PD may be separated from each other by scribe lines PL. The units PD may be separated from each other by a singulation technique. The panel PF may include a unit PD-1 at a central region and a unit PD-2 at a corner (or peripheral region). As shown in FIG. 17, different columns of the wafer WF may include different quantities of the units WD. Different rows of the wafer WF may include different quantities of the units WD. As shown in FIG. 18, different columns of the panel PF may include the same number of the units PD. Different rows of the panel PF may include the same number of the units PD. As shown in FIG. 17, the scribe line WL is not parallel to the edge of the wafer WF. As shown in FIG. 18, the scribe line PL may be substantially parallel to the edge of the panel PF.

A layer (e.g., dielectric layer or conductive layer) may be formed on the wafer WF by spin-on coating, sputtering, plating or other techniques. A layer (e.g., dielectric layer or conductive layer) may be formed on the panel PF by spray coating, doctor blade coating, roll-to-roll coating, sputtering, plating, or other techniques. Since the panel PF has a rectangular profile, the circuit pattern on the panel PF may exhibit greater thickness at the corners (or peripheral region) and reduced thickness in the central region, a variation attributed to corona discharge. For example, the circuit layer of the unit PD-2 has a greater thickness, and the circuit layer of the unit PD-1 has a smaller thickness. In comparison, the thickness of the circuit layers of the wafer WF may be affected by loading effect or other factors, resulting in thickness differences between units in different locations. To improve thickness uniformity, the panel PF may have dummy patterns. The density of these dummy patterns, which serve no electrical function, is higher at the corners (or peripheral region) than in the central region. For example, the density of the dummy patterns abutting or within the unit PD-2 may be greater than the density of the dummy patterns abutting or within the unit PD-1. The units WD on the wafer WF may be arranged with a higher density in the central region and a lower density in the peripheral region. The units PD on the panel PF may be arranged with substantially the same density in the central region and in the corners (or peripheral region).

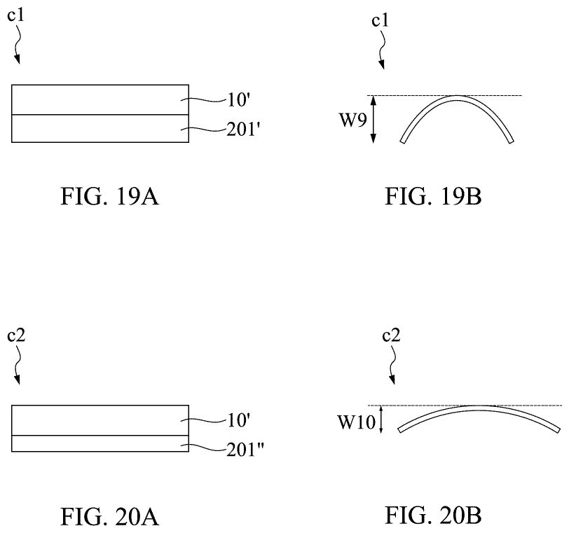

FIGS. 19A, 19B, 20A, and 20B illustrate the change in warpage at various stages of a comparative example. FIGS. 19A and 20A illustrate cross-sectional views of a comparative electronic device, and FIGS. 19B and 20B illustrate the warpage of structures as shown in FIGS. 19A and 20A, respectively.

As shown in FIGS. 19A and 19B, the structure c1 may include a substrate 10′ and a layer 201′. The substrate 10′ and layer 201′ may be the same as or similar to the substrate 10 and layer 201, respectively. The structure c1 may have a warpage W9. As shown in FIGS. 20A and 20B, the structure c2 may include the substrate 10′ and a layer 201″. The layer 201″ may have a thickness less than that of the layer 201′. The structure c2 may have a warpage W10 less than the warpage W9. The ratio of the warpage W10 to the warpage W9 may be about 0.4.

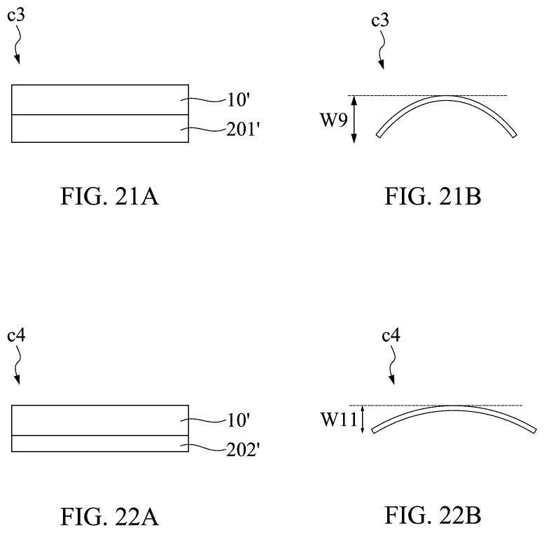

FIGS. 21A, 21B, 22A, and 22B illustrate the change in warpage at various stages of a comparative example. FIGS. 21A and 22A illustrate cross-sectional views of a comparative electronic device, and FIGS. 21B and 22B illustrate the warpage of structures as shown in FIGS. 21A and 22A, respectively.

As shown in FIGS. 21A and 21B, the structure c3 may include the substrate 10′ and the layer 201′. The structure c3 may have a warpage W9. As shown in FIGS. 22A and 22B, the structure c2 may include the substrate 10′ and a layer 202′ replacing the layer 201′. The coefficient of thermal expansion of the layer 202′ is closer to the substrate 10′ than the layer 201′ is. The structure c4 may have a warpage W11 less than the warpage W9. The ratio of the warpage W11 to the warpage W9 may be about 0.6.

Compared to the comparative examples which have only one warpage-adjusting layer on one side of the substrate, the embodiments of the present disclosure can effectively eliminate warpage during the manufacturing process, thereby significantly improving yield.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only and that practical implementations of the structures described herein can be spatially arranged in any orientation or manner, provided that the merits of arrangements of this disclosure are not deviated from by such an arrangement.

As used herein, the term “vertical” is used to refer to upward and downward directions, whereas the term “horizontal” refers to directions transverse to the vertical directions.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to #1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to #1°, less than or equal to ±0.5°, less than or equal to ±0.1°, or less than or equal to ±0.05°.

Two surfaces can be deemed to be coplanar or substantially coplanar if a displacement between the two surfaces is no exceeding 5 μm, no exceeding 2 μm, no exceeding 1 μm, or no exceeding 0.5 μm. A surface can be deemed to be substantially flat if a displacement between the highest point and the lowest point of the surface is no exceeding 5 μm, no exceeding 2 μm, no exceeding 1 μm, or no exceeding 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity exceeding approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit, and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a temperature-sensitive structure having a first surface and a second surface opposite to the first surface;
a first multilayer structure disposed under the first surface of the temperature-sensitive structure and configured to cause a first residual stress in response to a first temperature change; and
a second multilayer structure disposed over the second surface and configured to cause a second residual stress in response to a second temperature change;
wherein the second residual stress substantially eliminates the first residual stress so that the temperature-sensitive structure, the first multilayer structure and the second multilayer structure constitute a less-temperature-sensitive structure.

2. The electronic device of claim 1, wherein the temperature-sensitive structure comprises a core and a first electronic component within the core.

3. The electronic device of claim 2, wherein the temperature-sensitive structure comprises a second electronic component, and a thickness of the first electronic component and a thickness of the second electronic component are different.

4. The electronic device of claim 2, further comprising:
a protection layer covering the core,
wherein the second multilayer structure comprises a conductive layer in contact with the protection layer.

5. The electronic device of claim 4, further comprising:
a via extending between the conductive layer and the first electronic component.

6. The electronic device of claim 1, wherein a thickness of the first multilayer structure and a thickness of the second multilayer structure are different.

7. The electronic device of claim 1, wherein a quantity of dielectric layers of the first multilayer structure is different from a quantity of dielectric layers of the second multilayer structure.

8. The electronic device of claim 2, wherein the second multilayer structure has a first conductive trace with a first line width/line space (L/S) and a second conductive trace with a second L/S different from the first L/S.

9. The electronic device of claim 8, wherein the first multilayer structure has a third conductive trace with a third L/S substantially equal to the first L/S.

10. The electronic device of claim 2, wherein the second multilayer structure has a first dielectric layer with a first thickness and a second dielectric layer with a second thickness less than the first thickness, and the first dielectric layer is closer to the temperature-sensitive structure than the second dielectric layer is.

11. An electronic device, comprising:
a substrate having a first surface and a second surface opposite to the first surface;
a first redistribution structure disposed under the first surface and having a first line width/line space (L/S);
a second redistribution structure disposed over the second surface and having a second L/S substantially equal to the first L/S; and
a third redistribution structure disposed over the second surface and having a third L/S different from the first L/S.

12. The electronic device of claim 11, further comprising:
a first electronic component and a second electronic component embedded within the substrate and having different thicknesses.

13. The electronic device of claim 12, further comprising:
a planarization layer covering the first electronic component and the second electronic component.

14. The electronic device of claim 13, wherein the planarization layer is disposed between the first electronic component and the second redistribution structure.

15. The electronic device of claim 11, wherein a first width of the first redistribution structure is greater than a second width of the substrate.

16. A method of manufacturing an electronic device, comprising:
providing a temperature-sensitive structure having a first surface and a second surface opposite to the first surface;
forming a first multilayer structure under the first surface of the temperature-sensitive structure and configured to cause a first residual stress in response to a first temperature change; and
forming a second multilayer structure over the second surface subsequent to forming the first multilayer structure and configured to cause a second residual stress in response to a second temperature change,
wherein the second residual stress substantially eliminates the first residual stress so that the temperature-sensitive structure, the first multilayer structure and the second multilayer structure constitute a less-temperature-sensitive structure.

17. The method of claim 16, wherein forming the temperature-sensitive structure comprises:
providing a core and defining an opening of the core; and
disposing a first electronic component and a second electronic component within the core.

18. The method of claim 17, further comprising:
forming a planarization layer covering the first electronic component and the second electronic component,
wherein the second multilayer structure is formed over the planarization layer.

19. The method of claim 16, wherein forming the second multilayer structure comprises:
forming a first redistribution structure, with a first line width/line space (L/S), over the second surface; and
forming a second redistribution structure, with a second L/S different from the first L/S, over the first redistribution structure of the temperature-sensitive structure.

20. The method of claim 19, further comprising:
sawing the first redistribution structure and the temperature-sensitive structure before forming the second redistribution structure.
